(19) United States
(12) Patent Application Publication
(10) Pub. No.: US 2026/0182121 A1
(43) Pub. Date: Jun. 25, 2026

(54) DISPLAY APPARATUS

(71) Applicant: SAMSUNG ELECTRONICS CO., LTD., Suwon-si (KR)

(72) Inventors: Seungjae KIM, Suwon-si (KR); Pilyong OH, Suwon-si (KR); Kwangjae LEE, Suwon-si (KR); Jaemin CHO, Suwon-si (KR)

(73) Assignee: SAMSUNG ELECTRONICS CO., LTD., Suwon-si (KR)

(21) Appl. No.: 19/383,120

(22) Filed: Nov. 7, 2025

Related U.S. Application Data
(63) Continuation of application No. PCT/KR2025/017780, filed on Nov. 3, 2025.

(30) Foreign Application Priority Data
Dec. 23, 2024 (KR) 10-2024-0194120

(51) Int. Cl. H10H 29/85; H10H 20/857; H10H 29/14

(52) U.S. Cl. CPC H10H 29/8506; H10H 20/857; H10H 29/142; H10H 29/8508; H10H 29/8581

(57) ABSTRACT

A display apparatus according to an embodiment of the present disclosure may include: a plurality of display modules, one or more of the plurality of display modules including a substrate and a plurality of inorganic light-emitting elements mounted on the substrate; and a frame configured to support the plurality of display modules such that the plurality of display modules are arranged horizontally in an M*N matrix form. The frame may include: a glass core layer; a first fiber-reinforced layer on a first surface of the glass core layer and configured to face the substrates of the plurality of display modules; and a second fiber-reinforced layer on a second surface of the glass core layer, which is opposite to the first surface.

### CROSS-REFERENCE TO RELATED APPLICATIONS

This application is a continuation of International Application No. PCT/KR 2025/017780, filed on Nov. 3, 2025, which claims priority to Korean Patent Application No. 10-2024-0194120, filed on Dec. 23, 2024 in the Korean Intellectual Property Office, the disclosures of which are incorporated by reference herein in their entirety.

### BACKGROUND

### 1. Field

The disclosure relates to a display apparatus that displays an image by combining modules on which self-emissive inorganic light-emitting elements are mounted on a substrate.

### 2. Description of Related Art

A display apparatus is a type of output device that visually displays data information such as characters and figures, as well as images.

In general, display apparatuses have primarily used liquid crystal panels, which require a backlight, or organic light-emitting diode (OLED) panels, which are formed of films of organic compounds that emit light on their own in response to an electric current. However, liquid crystal panels suffer from slow response times, high power consumption, and difficulty in compacting (i.e., minimizing in size) because they are not self-luminous and require backlighting. Meanwhile, OLED panels do not require backlighting and thus may be made thinner due to their self-emissive nature. However, they are susceptible to burn-in, a phenomena in which previous images remain partially visible after the display changes due to degradation of sub-pixels when the same screen is displayed for a prolonged period of time.

Accordingly, as a new panel to replace them, micro LED or μLED display panels, in which inorganic light-emitting elements are mounted on a substrate and the inorganic light-emitting elements themselves are used as pixels, are being researched.

A micro LED panel is a type of the flat display panels that includes a plurality of inorganic LEDs, each of which is 100 micrometers or less.

Such LED panels are also self-emissive elements, but since they are inorganic light-emitting elements, the burn-in phenomenon of OLEDs does not occur, and they have excellent luminance, resolution, power consumption, and durability.

Compared to liquid crystal display (LCD) panels that require backlighting, micro LED display panels offer better contrast, response time, and energy efficiency. Both organic OLEDs and micro LEDs, which are inorganic light-emitting elements, are energy efficient, but micro LEDs have higher brightness, luminous efficiency, and longer lifespan than OLEDs.

In addition, by arranging LEDs in pixel units on a circuit board, display modules may be manufactured on a substrate basis, allowing for ease of production of displays in various resolutions and screen sizes according to consumer demand.

### SUMMARY

One or more embodiments of the present disclosure provides a display apparatus with improved manufacturing efficiency.

An embodiment of the present disclosure provides a display apparatus with a lightweight.

An embodiment of the present disclosure provides a display apparatus with reduced thickness.

An embodiment of the present disclosure provides a seamless display apparatus.

An embodiment of the present disclosure provides a display apparatus including a frame with an improved structure.

Technical tasks to be achieved in this document are not limited to the technical tasks mentioned above, and other technical tasks not mentioned will be clearly understood by those skilled in the art from the description below.

A display apparatus according to an embodiment of the present disclosure may include: a plurality of display modules, one or more of the plurality of display modules including a substrate and a plurality of inorganic light-emitting elements mounted on the substrate; and a frame configured to support the plurality of display modules such that the plurality of display modules are arranged horizontally in an M*N matrix form. The frame may include: a glass core layer; a first fiber-reinforced layer on a first surface of the glass core layer and configured to face the substrates of the plurality of display modules; and a second fiber-reinforced layer on a second surface of the glass core layer, which is opposite to the first surface.

A display apparatus according to an embodiment of the present disclosure may include: a plurality of micro light-emitting diode (LED) modules; a frame facing rear surfaces of the plurality of micro LED modules and configured to maintain a gap between the plurality of micro LED modules; and a chassis on a rear side of the plurality of micro LED modules and a rear side of the frame. The frame may include: a first fiber-reinforced layer facing the rear surfaces of the plurality of micro LED modules and including at least one of carbon fiber reinforced polymer (CFRP) and glass fiber reinforced polymer (GFRP); a second fiber-reinforced layer spaced rearwardly from the first fiber-reinforced layer, facing the chassis, and including a same material as the first fiber-reinforced layer; a glass core layer between the first fiber-reinforced layer and the second fiber-reinforced layer; a first adhesive layer between the first fiber-reinforced layer and the glass core layer and configured to bond the first fiber-reinforced layer and the glass core layer; and a second adhesive layer between the second fiber-reinforced layer and the glass core layer and configured to bond the second fiber-reinforced layer and the glass core layer.

### BRIEF DESCRIPTION OF DRAWINGS

FIG. 1 is a perspective view of a display apparatus according to an embodiment of the present disclosure.

FIG. 2 is an exploded view of main configurations of the display apparatus according to an embodiment of the present disclosure.

FIG. 3 is an enlarged cross-sectional view of some configurations of a display module according to an embodiment of the present disclosure.

FIG. 4 is a perspective view illustrating a rear surface of the display module according to an embodiment of the present disclosure.

FIG. 5 is a perspective view of a frame according to an embodiment of the present disclosure.

FIG. 6 is a cross-sectional view of the frame according to an embodiment of the present disclosure.

FIG. 7 is an enlarged view of an example of a fiber-reinforced layer according to an embodiment of the present disclosure.

FIG. 8 is an enlarged view of an example of a fiber-reinforced layer according to an embodiment of the present disclosure.

FIG. 9 is an enlarged view of an example of a fiber-reinforced layer according to an embodiment of the present disclosure.

FIG. 10 is an enlarged view of an example of a fiber-reinforced layer according to an embodiment of the present disclosure.

FIG. 11 is an exploded perspective view of an example of a frame according to an embodiment of the present disclosure.

FIG. 12 is an exploded perspective view of an example of a frame according to an embodiment of the present disclosure.

FIG. 13 is a cross-sectional view of the plurality of display modules and the frame of the display apparatus according to an embodiment of the present disclosure.

FIG. 14 is an enlarged cross-sectional view of a portion of the plurality of display modules and the frame of the display apparatus according to the embodiment of the present disclosure shown in FIG. 13.

### DETAILED DESCRIPTION

Various embodiments of the present document and terms used therein are not intended to limit the technical features described in this document to specific embodiments, and should be understood to include various modifications, equivalents, or substitutes of the corresponding embodiments.

In connection with the description of the drawings, similar reference numerals may be used for similar or related components.

The singular form of a noun corresponding to an item may include one or a plurality of the items unless clearly indicated otherwise in a related context.

In this document, phrases, such as “A or B”, “at least one of A and B”, “at least one of A or B”, “A, B or C”, “at least one of A, B and C”, and “at least one of A, B, or C” may include any one or all possible combinations of items listed together in the corresponding phrase among the phrases.

The term of “and/or” includes a plurality of combinations of relevant items or any one item among a plurality of relevant items.

In addition, the terms “portion”, “part”, “unit”, “module” or “member” may be implemented in hardware or software. Depending on the embodiments, a plurality of “portions”, “parts”, “units”, “modules” or “members” may be implemented as a single element, or a single “portion”, “part”, “unit”, “module” or “member” may include a plurality of elements.

It will be understood that, although the terms “first”, “second”, “primary”, “secondary”, etc., may be used herein to describe various elements, but elements are not limited by these terms. These terms are only used to distinguish one element from another element. For example, without departing from the scope of the disclosure, a first element may be termed as a second element, and a second element may be termed as a first element. The term of “and/or” includes a plurality of combinations of relevant items or any one item among a plurality of relevant items.

When an element (e.g., a first element) is referred to as being “(functionally or communicatively) coupled” or “connected” to another element (e.g., a second element), the first element may be connected to the second element, directly (e.g., wired), wirelessly, or through a third element.

In this disclosure, the terms “including”, “comprising”, “having”, and the like are used to specify features, numbers, steps, operations, elements, components, or combinations thereof, but do not preclude the presence or addition of one or more of the features, numbers, steps, operations, elements, components, or combinations thereof.

When an element is said to be “connected”, “coupled”, “supported”, or “contacted” to, with, or by another element, this includes not only when elements are directly connected, coupled, supported or contacted, but also when elements are indirectly connected, coupled, supported or contacted through a third element.

Throughout the description, when an element is “on” another element, this includes not only when the element is in contact with the other element, but also when there is another element between the two elements.

In addition, in the present disclosure, the meaning of “identical” includes cases where properties are similar to each other or similar within a certain range. Furthermore, identical means “substantially identical”. The meaning of substantially identical should be understood to include numerical values within manufacturing error ranges or differences within a range that is insignificant with respect to a reference numerical value as falling within the scope of ‘identical’.

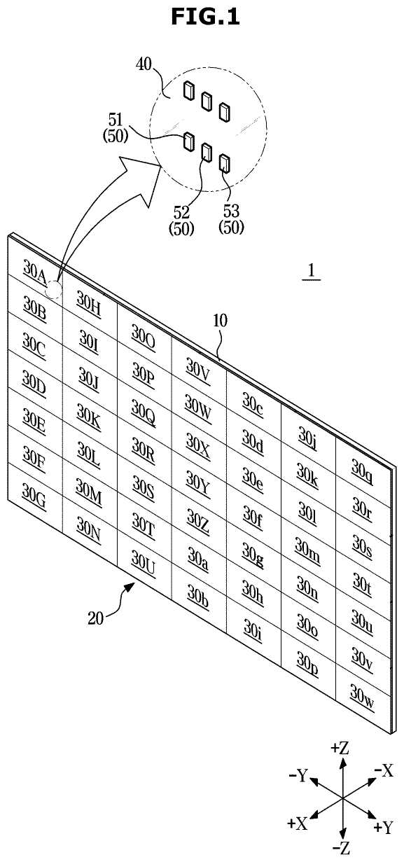

As used herein, the terms “front (or forward)”, “rear (or back, rearward)”, “left”, “right”, “up (or top)”, “down (or bottom)” and the like may be defined with reference to the drawings, and may not be intended to limit the shape and position of each component. For example, “front” and “rear” may each be defined relative to an x-axis shown in the drawings. For example, “left” and “right” may each be defined relative to a Y axis shown in the drawings. For example, “up” and “down” may each be defined relative to a Z axis shown in the drawings. For example, a direction in which the image is displayed relative to a display apparatus 1 shown in FIG. 1 may be defined as forward (+X direction), and a direction opposite to forward may be defined as backward (−X direction).

In the drawings, some configurations of the display apparatus 1, including a plurality of inorganic light-emitting elements 50, may be micro-unit configurations having sizes from several μm to several hundred μm. Accordingly, for ease of description, the scales of some configurations (e.g., the plurality of inorganic light-emitting elements 50, a substrate 40, a frame 100, etc.) may be shown exaggerated.

Hereinafter, exemplary embodiment(s) of the present disclosure will be described in detail with reference to the accompanying drawings.

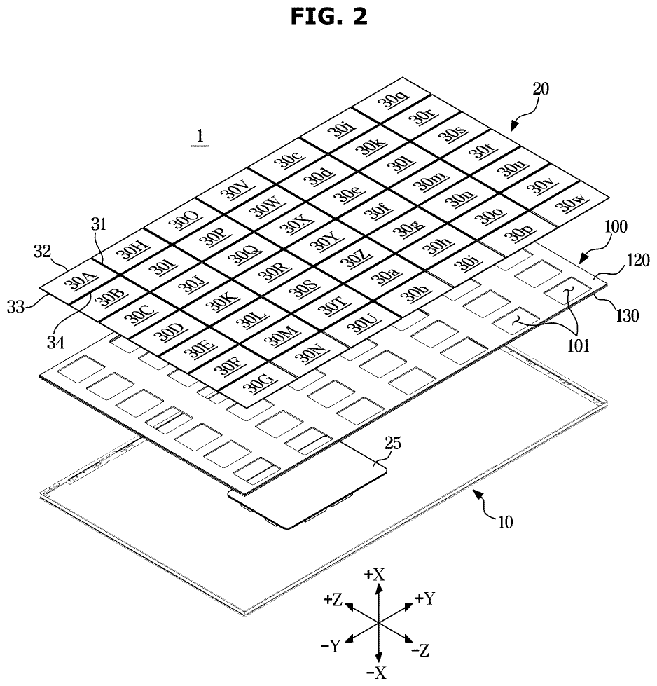

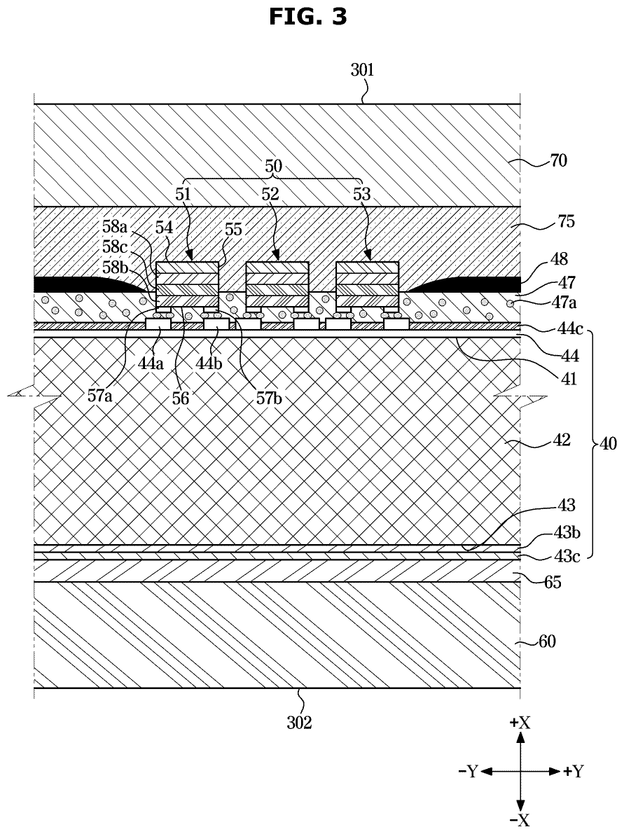

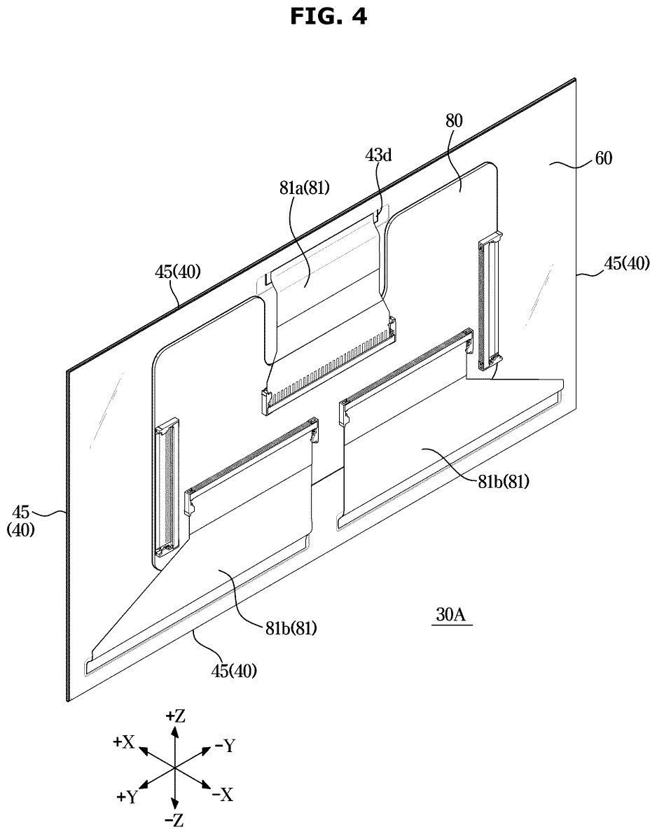

FIG. 1 is a perspective view of a display apparatus according to an embodiment of the present disclosure. FIG. 2 is an exploded view of main configurations of the display apparatus according to an embodiment of the present disclosure. FIG. 3 is an enlarged cross-sectional view of some configurations of a display module according to an embodiment of the present disclosure. FIG. 4 is a perspective view illustrating a rear surface of the display module according to an embodiment of the present disclosure.

The display apparatus 1 may be a device that displays information, materials, data, and the like in the form of characters, shapes, graphs, images, and the like. For example, a television (TV), a personal computer (PC), a mobile, a digital signage, or the like may be implemented as the display apparatus 1.

According to an embodiment of the present disclosure, as shown in FIGS. 1 and 2, the display apparatus 1 may include a display panel 20 configured to display an image, a board 25 configured to drive and/or control the display panel 20, a frame 100 configured to support the display panel 20, and a chassis 10 configured to cover a rear side of the display panel 20 and a rear side of the frame 100.

The display panel 20 may include a plurality of display modules 30A-30w. The display panel 20 may include a drive board to drive each of the display modules 30A-30w and a timing controller (TOCN) board to generate timing signals necessary to control each of the display modules 30A-30w.

The board 25 may include a circuit board to drive and/or control the display apparatus 1. In an example, the board 25 may include at least one of a power board to supply power to the display panel 20, a control board to control the overall operation of the display panel 20, and a communication board to communicate with an external device.

The chassis 10 may support the display panel 20 and/or the frame 100. The chassis 10 may be configured to cover a rear side of the plurality of display modules 30A-30w and/or the rear side of the frame 100. In an example, the chassis 10 may be disposed to face a second fiber-reinforced layer 130 of the frame 100, which will be described later.

The chassis 10 may be installed on a floor via a stand, or may be mounted on a wall via a hanger, or the like. The chassis 10 may be referred to as a case 10, a housing 10, or the like.

The plurality of display modules 30A-30w may be arranged vertically and horizontally so as to be adjacent to each other. The plurality of display modules 30A-30w may be arranged in an M * N matrix. In the present embodiment, the plurality of display modules 30A-30 w are provided in 49, and arranged in a 7*7 matrix. However, there is no limitation on the number and arrangement method of the plurality of display modules 30A-30w.

The plurality of display modules 30A-30w may be installed on the frame 100. The plurality of display modules 30A-30w may be mounted on the frame 100. The plurality of display modules 30A-30w may be coupled to the frame 100. The plurality of display modules 30A-30w may be installed on the frame 100 using a variety of methods known in the art, such as magnetically, mechanically, adhesively, etc. The chassis 10 may be coupled to the rear of the frame 100, and may form a rear exterior of the display apparatus 1. The frame 100 may include a plurality of module openings 101 formed corresponding to the plurality of display modules 30A-30w.

The chassis 10 may include a metal material. Accordingly, heat generated by the plurality of display modules 30A-30w and the frame 100 may be easily conducted to the chassis 10, thereby increasing heat dissipation efficiency of the display apparatus 1.

Unlike what is shown in the drawings, each single display module in the plurality of display modules 30A-30w may be applicable to a display apparatus. In other words, each of the display modules 30A-30w may be installed and applied as a single unit to wearable devices, portable devices, handheld devices, and various electronic products or electrical equipment that require displays. As shown in the drawings, the display modules 30A-30w may be applied to display apparatuses, such as monitors for PCs, high-resolution TVs and signage, electronic displays, and the like through a plurality of assembly arrangements in a matrix type.

The plurality of display modules 30A-30w may have substantially identical configurations to each other. Accordingly, the description of any one display module described herein may be equally applicable to all other display modules.

A first display module 30A of the plurality of display modules 30A-30w will be described as an example.

The first display module 30A may be formed in a quadrilateral (or quadrangle) type. The first display module 30A may be provided in a rectangle type shape or a square type shape. However, the shape is not particularly limited thereto and may include other shapes besides quadrilateral.

The first display module 30A may include edges 31, 32, 33 and 34 formed based on the front (+X direction).

As shown in FIG. 3, each of the plurality of display modules 30A-30w may include a substrate 40 and a plurality of inorganic light-emitting elements 50 mounted on the substrate 40. The plurality of inorganic light-emitting elements 50 may be mounted on a mounting surface 41 of the substrate 40. In FIG. 3, for ease of description, thicknesses of some configurations, including the substrate 40, may be shown to be exaggeratedly thick.

The substrate 40 may be formed in a quadrilateral type. As described above, each of the plurality of display modules 30A-30w may be provided in a quadrilateral shape, and the substrate 40 may be formed in a quadrilateral shape corresponding thereto. The substrate 40 may be provided in a rectangular or square shape. The substrate 40 may include four edges corresponding to the edges 31, 32, 33 and 34 of the first display module 30A.

The substrate 40 may include a base substrate 42, the mounting surface 41 forming one surface of the base substrate 42, a rear surface 43 forming the other surface of the base substrate 42 and disposed on an opposite side of the mounting surface 41, and side surfaces 45 disposed between the mounting surface 41 and the rear surface 43.

The mounting surface 41 may be provided to face the plurality of inorganic light-emitting elements 50. The mounting surface 41 may be provided to face a cover 70, which will be described later. The rear surface 43 may be provided to face the chassis 10.

The substrate 40 may include a thin film transistor (TFT) 44 configured to drive the inorganic light-emitting elements 50. The TFT layer 44 may be formed on the base substrate 42. The base substrate 42 may include a glass material, and in this case, the substrate 40 may be referred to as a glass substrate 40. In other words, the substrate 40 may include a chip on glass (COG) type substrate.

TFTs constituting the TFT layer 44 are not limited to a particular structure or type, and may be configured with various embodiments. In other words, the TFTs of the TFT layer 44 according to an embodiment may be implemented as low temperature poly silicon (LTPS) TFTs, oxide TFTs, or Si (poly silicon, or a-silicon) TFTs, as well as organic TFTs, graphene TFTs, and the like.

The TFT layer 44 may be replaced by a complementary metal-oxide semiconductor (CMOS) type, an n-type MOSFET, or a p-type MOSFET transistor when the base substrate 42 of the substrate 40 is provided as a silicon wafer.

The substrate 40 may include a first pad electrode 44a and a second pad electrode 44b. The first pad electrode 44a and the second pad electrode 44b may be configured to electrically connect the inorganic light-emitting elements 50 and the TFT layer 44. In an example, the first pad electrode 44a and the second pad electrode 44b may be provided as a pair.

The plurality of inorganic light-emitting elements 50 may include an inorganic light-emitting element 50 formed of an inorganic material and having a width, length, and height of several μm to several tens of μm, respectively. For example, a length of a short side of the width, length, and height of the inorganic light-emitting element 50 may be 100 μm or less. For example, the inorganic light-emitting element 50 may be picked up from a sapphire or silicon wafer and transferred to the substrate 40. For example, the inorganic light-emitting element 50 may be picked up and transferred via various methods, such as an electrostatic method using an electrostatic head or a stamp method using an elastic polymer material such as polydimethylsiloxane (PDMS) or silicon as a head. However, the present disclosure is not limited to the examples described above, and the inorganic light-emitting element 50 may be mounted on the substrate 40 through various methods.

Meanwhile, the plurality of inorganic light-emitting elements 50 may be referred to as a plurality of micro LEDs 50. The plurality of display modules 30A-30w may be referred to as a plurality of micro LED modules 30A-30w.

In an example, each of the plurality of inorganic light-emitting elements 50 may be a light-emitting structure including a first semiconductor 58a, an active layer 58c, a second semiconductor 58b, a first contact electrode 57a, and a second contact electrode 57b.

Each of the plurality of inorganic light-emitting elements 50 may include the first semiconductor 58a and the second semiconductor 58b. The second semiconductor 58b may be closer to the substrate 40 than the first semiconductor 58a. The first semiconductor 58a and the second semiconductor 58b may be disposed with an active layer 58c therebetween. One of the first semiconductor 58a and the second semiconductor 58b may be an n-type semiconductor, and the other of the first semiconductor 58a and the second semiconductor 58b may be a p-type semiconductor. Electrons may be present in one of the first semiconductor 58a and the second semiconductor 58b, and holes may be present in the other of the first semiconductor 58a and the second semiconductor 58b. Light may be generated while these electrons and holes recombine in the active layer 58c.

Each of the plurality of inorganic light-emitting elements 50 may include the active layer 58c. The active layer 58c may include a material that emits light by recombination of electrons and holes. The active layer 58c may be disposed between the first semiconductor 58a and the second semiconductor 58b. The active layer 58c may be formed between the first semiconductor 58a and the second semiconductor 58b. The active layer 58c may be provided to generate light.

Each of the plurality of inorganic light-emitting elements 50 may include a light-emitting surface 54. The inorganic light-emitting element 50 may include a bottom surface 56 disposed on an opposite side of the light-emitting surface 54. The inorganic light-emitting element 50 may include a side surface 55 connecting the light-emitting surface 54 and the bottom surface 56. The light-emitting surface 54 may be disposed to face forward. The light-emitting surface 54 may emit light toward the cover 70.

Each of the plurality of inorganic light-emitting elements 50 may include the first contact electrode 57a and the second contact electrode 57b. Although not clearly shown in the drawings, one of the first contact electrode 57a and the second contact electrode 57b may be electrically connected to the first semiconductor 58a, and the other may be electrically connected to the second semiconductor 58b. The first contact electrode 57a may be configured to correspond to the first pad electrode 44a, and the second contact electrode 57b may be configured to correspond to the second pad electrode 44b. In an example, the first contact electrode 57a and the second contact electrode 57b may be provided as a pair.

For example, the first contact electrode 57a and the second contact electrode 57b may be in the form of a flip chip type, where they are disposed horizontally and face in the same direction (a direction opposite to a light emitting direction).

The first contact electrode 57a and the second contact electrode 57b may be formed on the bottom surface 56. In other words, the first contact electrode 57a and the second contact electrode 57b may be disposed on the opposite side of the light-emitting surface 54 and consequently, may be disposed on the opposite side of a direction in which light is irradiated. The first contact electrode 57a and the second contact electrode 57b may be disposed to face the mounting surface 41 and may be arranged to be electrically connected to the TFT layer 44. The light-emitting surface 54 may be arranged to irradiate light in a direction opposite to a direction in which the first contact electrode 57a and the second contact electrode 57b are disposed.

Accordingly, light generated in the active layer 58c may be directed through the light-emitting surface 54 without interference with the first contact electrode 57a and/or the second contact electrode 57b.

The first contact electrode 57a and the second contact electrode 57b may be electrically connected to the first pad electrode 44a and the second pad electrode 44b formed on the mounting surface 41 side of the substrate 40, respectively.

Each of the plurality of display modules 30A-30w may include a conductive adhesive layer 47 configured to electrically connect the inorganic light-emitting element 50 and the substrate 40. The conductive adhesive layer 47 may be configured to mediate an electrical bonding between the contact electrodes 57a and 57b and the pad electrodes 44a and 44b. The conductive adhesive layer 47 may electrically bond the first contact electrode 57a and the first pad electrode 44a, and the second contact electrode 57b and the second pad electrode 44b. The conductive adhesive layer 47 may be disposed on the substrate 40. At least a portion of the conductive adhesive layer 47 may be disposed between the first contact electrode 57a and the first pad electrode 44a and between the second contact electrode 57b and the second pad electrode 44b.

In an example, the conductive adhesive layer 47 may be an anisotropic conductive layer. The anisotropic conductive layer may be an anisotropic conductive adhesive applied over a protective film and may have a structure in which conductive balls 47a are dispersed in an adhesive resin. The conductive balls 47a may be conductive spheres encapsulated by a thin insulating film and may electrically connect conductors to each other by breaking the insulating film under pressure.

When pressure is applied to the anisotropic conductive layer in mounting the plurality of inorganic light-emitting elements 50 to the substrate 40, the insulating film of the conductive ball 47a may be broken to electrically connect the contact electrodes 57a and 57b of the inorganic light-emitting element 50 to the pad electrodes 44a and 44b of the substrate 40, respectively.

The anisotropic conductive layer 47 may include an anisotropic conductive film (ACF) in the form of a film and/or an anisotropic conductive paste (ACP) in the form of a paste.

However, the present disclosure is not limited to the example described above, and the conductive adhesive layer 47 may include a solder or any other suitable conductive material. After the plurality of inorganic light-emitting elements 50 are aligned on the substrate 40, the plurality of inorganic light-emitting elements 50 may be bonded to the substrate 40 through a reflow process.

The plurality of inorganic light-emitting elements 50 may include a red light-emitting element 51, a green light-emitting element 52, and a blue light-emitting element 53, and the light-emitting elements 50 may be mounted on the mounting surface 41 of the substrate 40 in a series of the red light-emitting element 51, the green light-emitting element 52, and the blue light-emitting element 53 as a single unit. A series of the red light-emitting element 51, the green light-emitting element 52, and the blue light-emitting element 53 may form a single pixel. In this case, the red light-emitting element 51, the green light-emitting element 52, and the blue light-emitting element 53 may each form a sub-pixel.

In an example, the red light-emitting element 51, the green light-emitting element 52, and the blue light-emitting element 53 may be arranged in a row at predetermined intervals, or may be arranged in a different form, such as a triangular form, but the shape is not limited thereto and may also include other shapes.

The substrate 40 may include a light absorbing layer 44c to absorb ambient light to enhance contrast. The light absorbing layer 44c may be formed on the entire mounting surface 41 side of the substrate 40. The light absorbing layer 44c may be formed between the TFT layer 44 and the conductive adhesive layer 47.

One or more of the plurality of display modules 30A-30w may further include a black matrix 48 formed between the plurality of inorganic light-emitting elements 50.

The black matrix 48 may perform a function of complementing the light absorbing layer 44c formed entirely on the mounting surface 41 side of the substrate 40. In other words, the black matrix 48 may enhance contrast of a screen by absorbing ambient light to cause the substrate 40 to appear black. Preferably, the black matrix 48 may have a black color.

According to an embodiment of the present disclosure, the black matrix 48 may be formed to be disposed between pixels formed by a series of the red light-emitting element 51, the green light-emitting element 52, and the blue light-emitting element 53. However, the black matrix 48 may be formed more finely to partition each of the light-emitting elements 51, 52, and 53 as sub-pixels within each pixel.

The black matrix 48 may be formed in a grid with a horizontal pattern and a vertical pattern so as to be disposed between the pixels.

The black matrix 48 may be formed by applying a light-absorbing ink on the conductive adhesive layer 47 via an ink-jet process and then curing it, or by coating the conductive adhesive layer 47 with a light-absorbing film.

In other words, the black matrix 48 may be formed in regions between the plurality of inorganic light-emitting elements 50 that are not mounted on the conductive adhesive layer 47 formed entirely on the mounting surface 41.

Each of the plurality of display modules 30A-30w may include the cover 70 configured to cover the substrate 40 and the plurality of inorganic light-emitting elements 50. The cover 70 may include a functional film having optical performance. The cover 70 may protect the substrate 40 and the plurality of inorganic light-emitting elements 50 from external forces. The cover 70 may prevent/reduce foreign matter and the like from entering the substrate 40 and the plurality of inorganic light-emitting elements 50. In an example, the cover 70 may form a front surface 301 of the display module.

Each of the plurality of display modules 30A-30w may include a cover adhesive layer 75. The cover adhesive layer 75 may be configured to adhere the cover 70 to the substrate 40 and the plurality of inorganic light-emitting elements 50. The cover adhesive layer 75 may minimize light loss or reflection. In an example, the cover adhesive layer 75 may be an optically clear adhesive (OCA) in the form of a film, such as a double-sided tape, or an optically clear resin (OCR) in the form of an amorphous liquid.

Each of the plurality of display modules 30A-30w may include a heat dissipation member (e.g., a heat sink) 60 configured to dissipate heat generated by the substrate 40. The heat dissipation member 60 may be attached to the rear surface 43 of the substrate 40. In an example, the heat dissipation member 60 may form a portion of a rear surface 302 of the display module.

Each of the plurality of display modules 30A-30w may include an adhesive tape 70 disposed between the rear surface 43 of the substrate 40 and bonded therebetween.

The plurality of inorganic light-emitting elements 50 may be sequentially electrically connected to an upper surface wiring layer, a side surface wiring, and a rear surface wiring layer 43b. The upper surface wiring layer may be formed on a rear side of the conductive adhesive layer 47. The side surface wiring may be formed on the side surface 45 of the substrate 40. The rear surface wiring layer 43b may be formed on the rear surface 43. An insulating layer 43c covering the rear surface wiring layer 43b may be provided on a rear side of the rear surface wiring layer 43b.

Referring to FIG. 4, the first display module 30A may include a drive circuit board 80 configured to electrically control the plurality of inorganic light-emitting elements 50 mounted on the mounting surface 41. The drive circuit board 80 may be formed as a printed circuit board (PCB).

The first display module 30A may include a flexible film 81 connecting the drive circuit board 80 and the rear surface wiring layer 43b such that the drive circuit board 80 is electrically connected to the plurality of inorganic light-emitting elements 50.

One end of the flexible film 81 may be connected to a rear connection pad 43d disposed on the rear surface 43 of the substrate 40 and electrically connected to the plurality of inorganic light-emitting elements 50.

The rear connection pad 43d may be electrically connected to the rear surface wiring layer 43b. Accordingly, the rear connection pad 43d may electrically connect the rear surface wiring layer 43b and the flexible film 81.

The flexible film 81, by being electrically connected to the rear connection pad 43d, may transmit power and electrical signals from the drive circuit board 80 to the plurality of inorganic light-emitting elements 50.

For example, the flexible film 81 may be formed from a flexible flat cable (FFC), a chip on film (COF), or the like.

The flexible film 81 may include a first flexible film 81a and a second flexible film 81b. The first flexible film 81a may transmit data signals from the drive circuit board 80 to the substrate 40. In an example, the first flexible film 81a may be provided as a COF. The second flexible film 81b may transmit power from the drive circuit board 80 to the substrate 40. In an example, the second flexible film 81b may be provided as an FFC.

In the drawings, the first flexible film 81a is shown as being provided as a single piece, the present disclosure is not limited to what is shown in the drawings, and the first flexible film 81a may be provided in a plurality. Although the drawing appears to show a plurality of second flexible films 81b, the present disclosure is not limited to what is shown in the drawings, and a single second flexible film 81b may be provided.

The drive circuit board 80 may be electrically connected to the board 25 (see FIG. 2). The board 25 may be disposed on the rear side of the frame 100, and the board 25 may be connected to the drive circuit board 80 via a cable.

The heat dissipation member 60 may be configured to be in contact with the substrate 40. The heat dissipation member 60 and the substrate 40 may be bonded by an adhesive tape 70 (see FIG. 3) disposed between the rear surface 43 of the substrate 40 and the heat dissipation member 60.

The heat dissipation member 60 may be formed of a material with high thermal conductivity or may be implemented in a configuration with high thermal conductivity. For example, the heat dissipation member 60 may be made of an aluminum material but is not particularly limited thereto and may include any suitable heat dissipation material.

Heat generated by the plurality of inorganic light-emitting elements 50 mounted on the substrate 40 and the TFT layer 44 of the substrate 40 may be transferred to the heat dissipation member 60. Heat generated in the substrate 40 may be easily transferred to the heat dissipation member 60, and the substrate 40 may be prevented from rising above a certain temperature.

An area of the substrate 40 may be larger than that of the heat dissipation member 60. With the substrate 40 and the heat dissipation member 60 bonded to each other, four edges of the substrate 40 may be provided to be disposed more outwardly than four edges of the heat dissipation member 60, relative to a center of the substrate 40 and the heat dissipation member 60.

Since a thermal expansion rate of the heat dissipation member 60 is generally higher than that of the substrate 40, an amount by which the heat dissipation member 60 expands may be higher than an amount by which the substrate 40 expands when heat is transferred to each of the display modules 30A-30w.

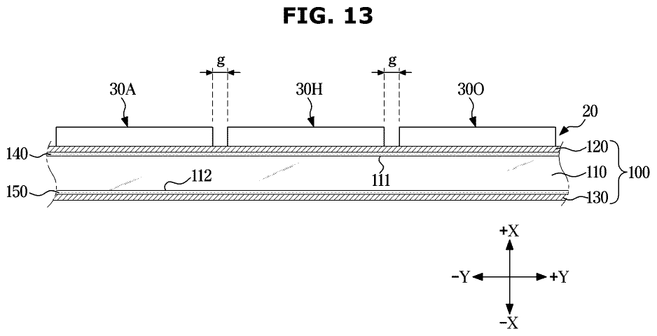

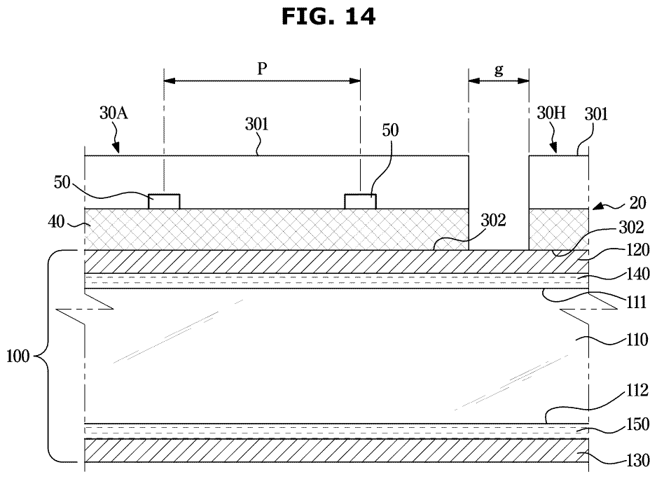

When the four edges of the substrate 40 are arranged corresponding to or further inward of the four edges of the heat dissipation member 60, the edges of the heat dissipation member 60 may protrude outwardly of the substrate 40 as the heat dissipation member 60 thermally expands. In this case, a gap g (see FIGS. 13 and 14) formed between each of the display modules 30A-30w may be formed irregularly. Accordingly, perceptibility of some seams may increase, thereby degrading a sense of unity of the screen of the display panel 20.

However, when the four edges of the substrate 40 are disposed outward of the four edges of the heat dissipation member 60, the heat dissipation member 60 may not protrude outward of the four edges of the substrate 40 even when the heat dissipation member 60 is thermally expanded, and accordingly, the gap g (see FIGS. 13 and 14) formed between each of the display modules 30A-30w may remain constant.

On the other hand, the substrate 40 may form a screen, be configured to be larger than the heat dissipation member 60, and be disposed in front of the heat dissipation member 60. Based on such, the gap g formed between the plurality of display modules 30A-30w substantially corresponds to a gap formed between the substrates 40. The user may not perceive the gap formed between the heat dissipation members 60 and may only perceive the gap formed between the substrates 40. In the present disclosure, in terms of maintaining the gap g formed between the plurality of display modules 30A-30w, the coefficient of thermal expansion of each of the display modules 30A-30w may be defined as approximately the coefficient of thermal expansion of the substrate 40. For example, when the substrate 40 is a glass substrate, it should be understood that the coefficient of thermal expansion of each display module may be substantially the same as or similar to the coefficient of thermal expansion of glass.

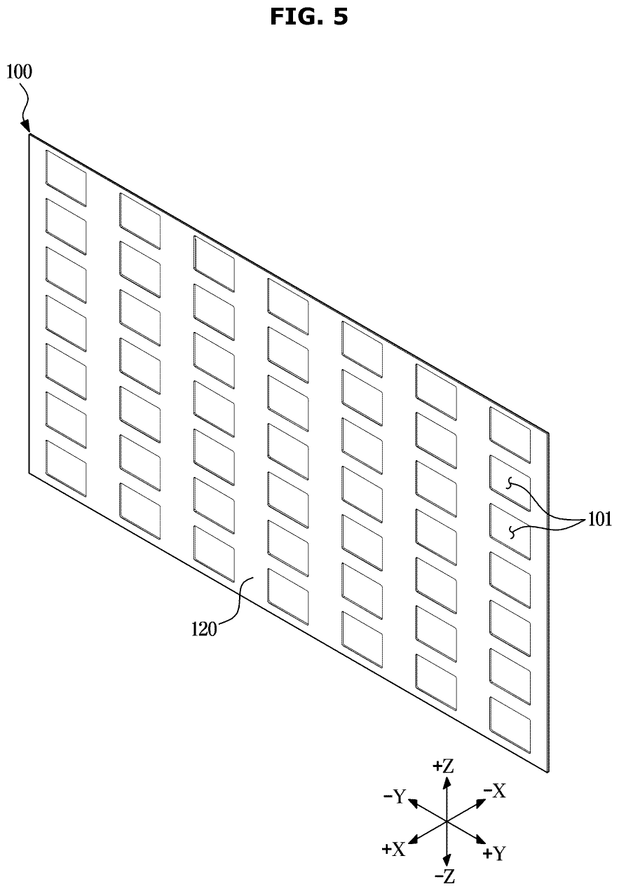

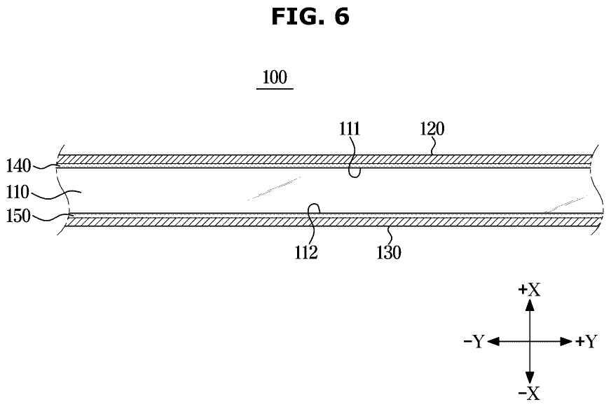

FIG. 5 is a perspective view of a frame according to an embodiment of the present disclosure. FIG. 6 is a cross-sectional view of the frame according to an embodiment of the present disclosure.

The frame 100 may support the plurality of display modules 30A-30w such that the plurality of display modules 30A-30w are arranged horizontally in a matrix of M*N (see FIG. 2). The frame 100 may be disposed on a rear side of the plurality of display modules 30A-30w. The frame 100 may be disposed on a front side of the chassis 10.

During operation of the display apparatus 1, heat may be generated in the substrate 40, the plurality of inorganic light-emitting elements 50 mounted on the substrate 40, and/or various electronic circuits (e.g., boards). At this time, coefficients of thermal expansion (CTE) of components constituting the display apparatus 1 may be different, and the amount of thermal expansion of each component may also be different. When the plurality of display modules 30A-30w of the display apparatus 1 is exposed to a high temperature for a long period of time, the gap g (see FIGS. 13 and 14) between the plurality of display modules 30A-30w may not remain constant. The gap g formed between the plurality of display modules 30A-30w may be formed irregularly, and accordingly, perceptibility of the seam formed by the gap g may increase, thereby degrading a sense of

### Unity of the Screen of the Display Panel 20.

According to an embodiment of the present disclosure, the frame 100 may have a structure for compensating for the amount of thermal expansion that occurs in different components of the display apparatus 1. The frame 100 may be configured to maintain a constant gap g formed between the plurality of display modules 30A-30w. To this end, the coefficient of thermal expansion of the frame 100 may be approximately the same as or similar to the coefficient of thermal expansion of each of the plurality of display modules 30A-30w. Thereby, perception of the seam in the display panel 20 may be minimized, and the sense of unity of the screen of the display panel 20 may not be degraded.

Referring to FIGS. 5 and 6, the frame 100 according to an embodiment of the present disclosure may include a glass core layer 110, a first fiber-reinforced layer 120, and a second fiber-reinforced layer 130.

The frame 100 may include the glass core layer 110. The glass core layer 110 may be disposed between the first fiber-reinforced layer 120 and the second fiber-reinforced layer 130. The glass core layer 110 may be disposed on a rear side of the first fiber-reinforced layer 120 and on a front side of the second fiber-reinforced layer 130.

The glass core layer 110 may include a first surface 111 and a second surface 112. The second surface 112 may be an opposite surface of the first surface 111. In an example, the first surface 111 of the glass core layer 110 may be adjacent to the plurality of display modules 30A-30w more than the chassis 10 (see FIG. 2). In an example, the second surface 112 of the glass core layer 110 may be adjacent to the chassis 10 more than the plurality of display modules 30A-30w (see FIG. 2).

The glass core layer 110 may include a glass material. In an example, the coefficient of thermal expansion of the glass core layer 110 may be approximately 3.0 μ/K to 4.0 μ/K. However, the present disclosure is not limited to the example described above, and a range of the coefficient of the thermal expansion of the glass core layer 110 may vary depending on the required performance of the display apparatus 1, the arrangement of components, and the like.

A thickness of the glass core layer 110 may vary depending on a required rigidity of the frame 100. Here, the thickness of the glass core layer 110 may be based on a stacking direction of a plurality of layers 110, 120 and 130 of the frame 100.

The frame 100 may include the first fiber-reinforced layer 120. The first fiber-reinforced layer 120 may be attached to the glass core layer 110. The first fiber-reinforced layer 120 may be attached to the first surface 111 of the glass core layer 110. The first fiber-reinforced layer 120 may be attached to the first surface 111 of the glass core layer 110 and disposed to face the plurality of display modules 30A-30w. The first fiber-reinforced layer 120 may be configured to face the substrates 40 of the plurality of display modules 30A-30w. The first fiber-reinforced layer 120 may be disposed to face the rear surface 302 (see FIGS. 3 and 14) of the plurality of display modules 30A-30w. The first fiber-reinforced layer 120 may be configured to form a front surface of the frame 100.

A coefficient of thermal expansion of the first fiber-reinforced layer 120 may be configured to correspond to the coefficient of thermal expansion of the glass core layer 110. The coefficient of thermal expansion of the first fiber-reinforced layer 120 may be substantially the same as or similar to the coefficient of thermal expansion of the glass core layer 110. The coefficient of thermal expansion of the first fiber-reinforced layer 120 may be substantially the same as or similar to the coefficient of thermal expansion of the plurality of display modules 30A-30w. In an example, the coefficient of thermal expansion of the first fiber-reinforced layer 120 may be substantially the same as or similar to the coefficient of thermal expansion of glass.

The first fiber-reinforced layer 120 may include at least one of carbon fiber reinforced polymer (CFRP) and glass fiber reinforced polymer (GFRP).

The frame 100 may include the second fiber-reinforced layer 130. The second fiber-reinforced layer 130 may be attached to the glass core layer 110. The second fiber-reinforced layer 130 may be attached to the second surface 112 of the glass core layer 110. The second fiber-reinforced layer 130 may be attached to the second surface 112 of the glass core layer 110 and disposed to face the chassis 10. The second fiber-reinforced layer 130 may be spaced apart from the first fiber-reinforced layer 120 in a rearward (−X direction). The second fiber-reinforced layer 130 may be configured to form a rear surface of the frame 100.

A coefficient of thermal expansion of the second fiber-reinforced layer 130 may be configured to correspond to the coefficient of thermal expansion of the glass core layer 110. The coefficient of thermal expansion of the second fiber-reinforced layer 130 may be substantially the same as or similar to the coefficient of thermal expansion of the glass core layer 110. The coefficient of thermal expansion of the second fiber-reinforced layer 130 may be substantially the same as or similar to the coefficient of thermal expansion of the plurality of display modules 30A-30w. In an example, the coefficient of thermal expansion of the second fiber-reinforced layer 130 may be substantially the same as or similar to the coefficient of thermal expansion of glass.

The second fiber-reinforced layer 130 may include at least one of CFRP and GFRP.

The first fiber-reinforced layer 120 and the second fiber-reinforced layer 130 may be formed of the same material. For example, the first fiber-reinforced layer 120 and the second fiber-reinforced layer 130 may be CFRP. For example, the first fiber-reinforced layer 120 and the second fiber-reinforced layer 130 may be GFRP. For example, a weaving method (i.e., type) of the first fiber-reinforced layer 120 and a weaving method of the second fiber-reinforced layer 130 may be the same. The glass core layer 110 may be provided in a sandwich structure between the same materials. Thereby, the frame 100 may have a stable structure. For example, when the frame 100 receives or loses heat, the first surface 111 and the second surface 112 of the glass core layer 110 may have approximately the same temperature change behavior.

In summary, the frame 100 may have a structure including the glass core layer 110, and the first fiber-reinforced layer 120 and the second fiber-reinforced layer 130 attached to two surfaces 111 and 112 of the glass core layer 110, respectively. The coefficient of thermal expansion of the first fiber-reinforced layer 120 and the coefficient of thermal expansion of the second fiber-reinforced layer 130 may be the same as or similar to the coefficient of thermal expansion of the glass core layer 110. In addition, the coefficient of thermal expansion of the first fiber-reinforced layer 120 and the coefficient of thermal expansion of the second fiber-reinforced layer 130 may be the same as or substantially similar to the coefficient of thermal expansion of the substrate 40. Since the coefficients of thermal expansions of the layers 110, 120 and 130 constituting the frame 100 are the same or substantially similar, thermal expansion rates (or thermal contraction rates) occurring in each layer may be approximately the same or substantially similar. As a result, flatness of the frame 100 may be maintained even when the frame 100 is exposed to heat. Internal stresses caused by temperature changes between the layers 110, 120 and 130 constituting the frame 100 may be minimized, and durability of the frame 100 may be improved and its lifespan may be extended.

The coefficient of thermal expansion of the first fiber-reinforced layer 120 of the frame 100 may be the same as or similar to the coefficient of thermal expansion of the plurality of display modules 30A-30w. Heat may be generated by various components during operation of the display apparatus 1. While the plurality of display modules 30A-30w are deformed by heat, the first fiber-reinforced layer 120 may be deformed corresponding to the plurality of display modules 30A-30w. Thereby, the plurality of display modules 30A-30w may be prevented from being damaged. Furthermore, the gap g formed between the plurality of display modules 30A-30w may be maintained constant. Since the gap g formed between the display modules 30A-30w is kept constant, the sense of unity of the screen of the display panel 20 may not be degraded.

Frames for a conventional display apparatus have a structure in which CFRP is laminated on a panel in which steel is attached to both surfaces of a polyethylene (PE) core layer. In such a structure, a process of attaching steel to both surfaces of the polyethylene (PE) core layer should be followed by a process of laminating the CFRP. In addition, as the frame including steel is applied to the display apparatus, the weight and thickness of the display apparatus may be increased. As a result, it is difficult to apply the conventional frame to a display having a large screen.

The frame 100 according to the present disclosure may have a three-layer structure including the glass core layer 110, the first fiber-reinforced layer 120, and the second fiber-reinforced layer 130. Accordingly, no additional process may be involved other than the process of attaching the first fiber-reinforced layer 120 and the second fiber-reinforced layer 130 to the two surfaces 111 and 112 of the glass core layer 110. As a result, the manufacturing efficiency of the frame 100 may be improved. In addition, compared to the conventional frame, the frame 100 according to the present disclosure may be relatively light in weight and thin in thickness. Thereby, the display apparatus 1 may be configured to be light and slim, and it is easy to manufacture a large screen.

The frame 100 may include a first adhesive layer 140. The first adhesive layer 140 may be disposed between the first fiber-reinforced layer 120 and the glass core layer 110. The first adhesive layer 140 may be configured to bond the first fiber-reinforced layer 120 and the glass core layer 110. A rear surface of the first fiber-reinforced layer 120 may be attached to the first surface 111 of the glass core layer 110 by the first adhesive layer 140.

The frame 100 may include a second adhesive layer 150. The second adhesive layer 150 may be disposed between the second fiber-reinforced layer 130 and the glass core layer 110. The second adhesive layer 150 may be configured to bond the second fiber-reinforced layer 130 and the glass core layer 110. A front surface of the second fiber-reinforced layer 130 may be attached to the second surface 112 of the glass core layer 110 by the second adhesive layer 150.

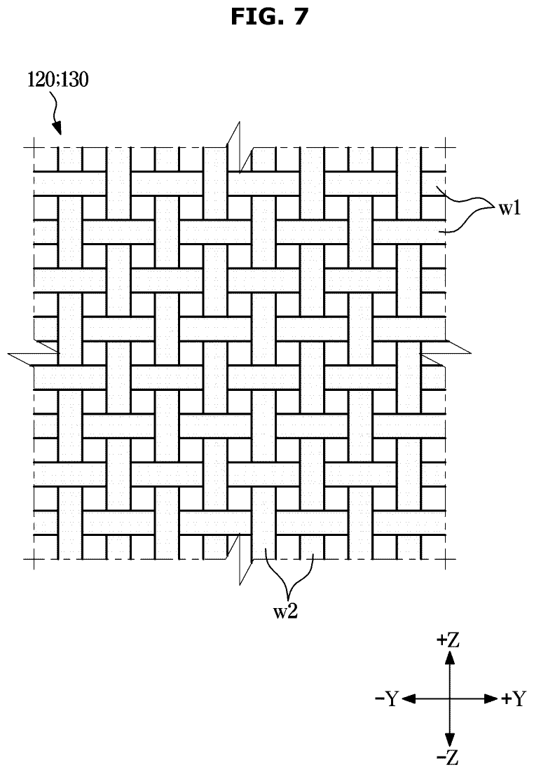

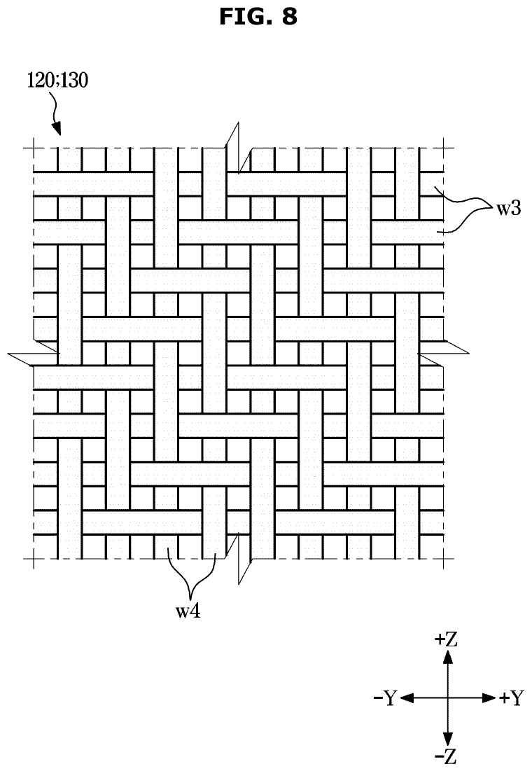

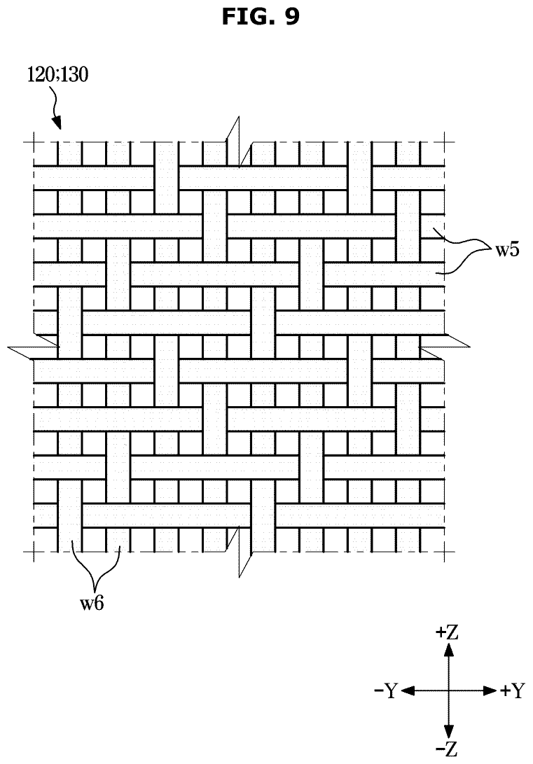

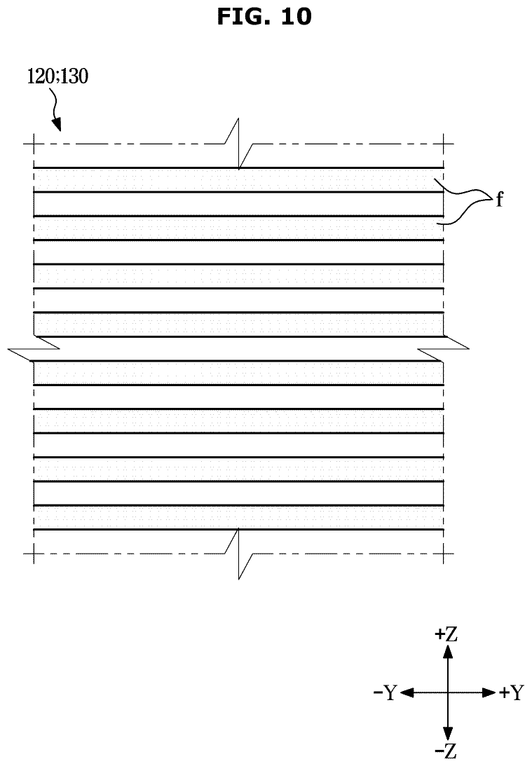

FIG. 7 is an enlarged view of an example of a fiber-reinforced layer according to an embodiment of the present disclosure. FIG. 8 is an enlarged view of an example of a fiber-reinforced layer according to an embodiment of the present disclosure. FIG. 9 is an enlarged view of an example of a fiber-reinforced layer according to an embodiment of the present disclosure. FIG. 10 is an enlarged view of an example of a fiber-reinforced layer according to an embodiment of the present disclosure.

Referring to FIGS. 7 to 11, the first fiber-reinforced layer 120 and the second fiber-reinforced layer 130 may each be formed by various weaving methods.

The coefficient of thermal expansion of the first fiber-reinforced layer 120 may be determined by (i.e., based on, corresponding to) a weaving method of the first fiber-reinforced layer 120. The coefficient of thermal expansion of the first fiber-reinforced layer 120 may vary depending on the weaving method of the first fiber-reinforced layer 120. The coefficient of thermal expansion of the second fiber-reinforced layer 130 may be determined by a weaving method of the second fiber-reinforced layer 130. The coefficient of thermal expansion of the second fiber-reinforced layer 130 may vary depending on the weaving method of the second fiber-reinforced layer 130.

The weaving method of the first fiber-reinforced layer 120 may vary depending on the coefficient of thermal expansion of the glass core layer 110 and/or a pitch p (see FIG. 14) between the plurality of inorganic light-emitting elements 50. The weaving method of the first fiber-reinforced layer 120 may be determined in consideration of the coefficient of thermal expansion of the glass core layer 110 and/or the pitch p between the plurality of inorganic light-emitting elements 50. The weaving method of the second fiber-reinforced layer 130 may vary depending on the coefficient of thermal expansion of the glass core layer 110 and/or the pitch p between the plurality of inorganic light-emitting elements 50. The weaving method of the second fiber-reinforced layer 130 may be determined in consideration of the coefficient of thermal expansion of the glass core layer 110 and/or the pitch p between the plurality of inorganic light-emitting elements 50. A detailed description thereof will be described later.

The first fiber-reinforced layer 120 may be configured as a fabric series (see FIGS. 7 to 9), in which the fibers are arranged to intersect in multiple directions, or as a unidirectional (UD) series (see FIG. 10), in which the fibers are arranged in a line in a single line in one direction. The second fiber-reinforced layer 130 may be configured as a fabric series (see FIGS. 7 to 9), in which the fibers are arranged to intersect in multiple directions, or a UD series (see FIG. 10), in which the fibers are arranged in a single line in one direction.

The first fiber-reinforced layer 120 may be configured to be woven by a Plain (see FIG. 7), Twill (see FIG. 8), Satin (see FIG. 9), or Unidirectional (UD) (see FIG. 10) method. The second fiber-reinforced layer 130 may be configured to be woven by a Plain (see FIG. 7), Twill (see FIG. 8), Satin (see FIG. 9), or Unidirectional (UD) (see FIG. 10) method.

For example, referring to FIG. 7, the first fiber-reinforced layer 120 and the second fiber-reinforced layer 130 may each be configured to be woven in a plain weave. The plain weave pattern may be configured such that a weft yarn w1 and a warp yarn w2 intersect in a 1:1 ratio. The plain weave pattern may be formed by repeating a method in which the weft yarn w1 passes over one warp yarn w2 and then passes under one warp yarn w2.

For example, referring to FIG. 8, the first fiber-reinforced layer 120 and the second fiber-reinforced layer 130 may each be configured to be woven in a twill weave. The twill weave pattern may be configured such that a weft yarn w3 intersects with two or more warp yarns w4 while skipping over them. The twill weave pattern may be configured such that the weft yarn w3 and the warp yarn w4 intersect in a 2:2 or 3:3 ratio. In the case where the weft yarn w3 and the warp yarn w4 intersect in a 2:2 ratio in the twill weave pattern, the pattern may be formed such that the weft yarn w3 continuously passes over two warp yarns w4 and then passes under two warp yarns w4 may be repeated.

For example, referring to FIG. 9, the first fiber-reinforced layer 120 and the second fiber-reinforced layer 130 may each be configured to be woven in a satin weave. The satin weave pattern may be configured such that a weft yarn w5 intersects with only one warp yarn w6 while skipping over multiple warp yarns w6. When manufactured in the satin weave pattern, the intersection points may be dispersed, resulting in a smooth surface of the fabric.

For example, referring to FIG. 10, the first fiber-reinforced layer 120 and the second fiber-reinforced layer 130 may each be configured to be woven in a UD weaving method. The UD weaving pattern may be configured such that fiber bundles are arranged in only one direction. In addition, a spacing between the fibers may be kept constant.

The coefficient of thermal expansion of the first fiber-reinforced layer 120 may vary depending on the weaving method (e.g., Plain, Twill, Satin, UD, etc.) of the first fiber-reinforced layer 120. This is because the ways the fibers are arranged in each weaving method may affect the thermal expansion behavior. Similarly, the coefficient of thermal expansion of the second fiber-reinforced layer 130 may vary depending on the weaving method or type (e.g., Plain, Twill, Satin, UD, etc.) of the second fiber-reinforced layer 130.

For example, depending on the weaving method of the first fiber-reinforced layer 120, a degree of crimp may vary. For example, depending on the weaving method of the second fiber-reinforced layer 130, a degree of crimp may vary. A crimp may refer to a bend (curved portion) that occurs when fibers intersect, i.e., cross. The more crimp, the higher the coefficient of thermal expansion, and the less crimp, the lower the coefficient of thermal expansion. For example, in the case of the UD method, the coefficient of thermal expansion may be relatively low compared to other weaving methods because there are relatively fewer crimps. For example, in the case of the Plain method, the coefficient of thermal expansion may be relatively high compared to other weaving methods because there are relatively more crimps. For example, the coefficient of thermal expansion may increase in the order of UD, Satin, Twill, and Plain methods. The weaving method of the first fiber-reinforced layer 120 may be selected according to a required coefficient of thermal expansion of the first fiber-reinforced layer 120, and the weaving method of the second fiber-reinforced layer 130 may be selected according to a required coefficient of thermal expansion of the second fiber-reinforced layer 130.

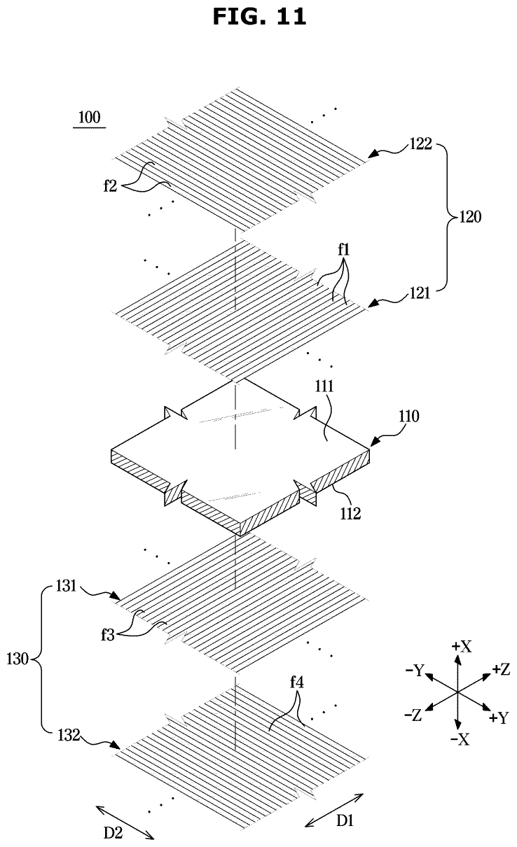

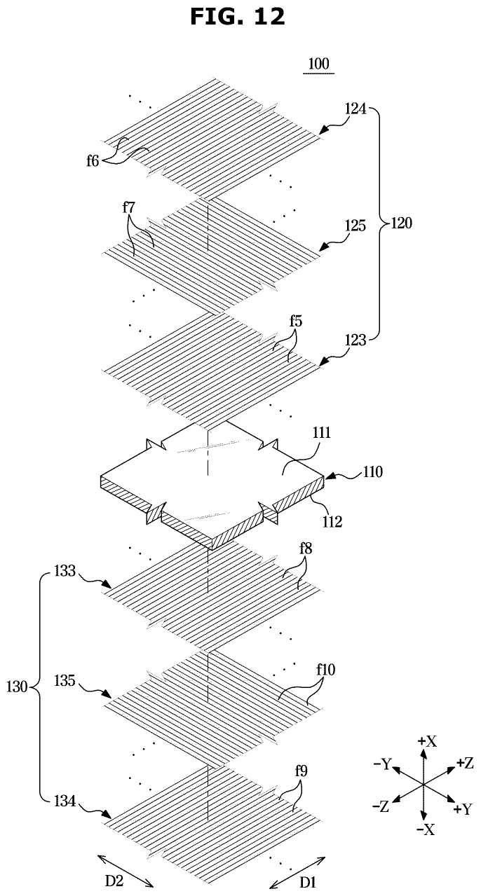

FIG. 11 is an exploded perspective view of an example of the frame according to an embodiment of the present disclosure. FIG. 12 is an exploded perspective view of an example of a frame according to an embodiment of the present disclosure.

Referring to FIGS. 11 and 12, the first fiber-reinforced layer 120 and the second fiber-reinforced layer 130 according to an embodiment of the present disclosure may be woven by the UD method. The frame 100 according to an embodiment of the present disclosure may include the glass core layer 110, the first fiber-reinforced layer 120 configured as a multilayer structure of a UD series, and the second fiber-reinforced layer 130 configured as a multilayer structure of a UD series.

For example, referring to FIG. 11, the frame 100 may include the glass core layer 110, the first fiber-reinforced layer 120 configured as a 2-ply structure of a UD series, and the second fiber-reinforced layer 130 configured as a 2-ply structure of a UD series.

The first fiber-reinforced layer 120 may include a first UD layer 121 and a second UD layer 122.

The first UD layer 121 may be attached to the first surface 111 of the glass core layer 110. The first UD layer 121 may include a first fiber bundle f1 extending in a first direction D1.

The second UD layer 122 may be laminated on a front surface of the first UD layer 121. The second UD layer 122 may be disposed to face the plurality of display modules 30A-30w (see FIG. 2). The second UD layer 122 may be configured to be in contact with the rear surface 302 (see FIGS. 3 and 14) of the plurality of display modules 30A-30w. The second UD layer 122 may include a second fiber bundle f2 extending in a second direction D2 different from the first direction D1.

The second fiber-reinforced layer 130 may include a third UD layer 131 and a fourth UD layer 132.

The third UD layer 131 may be attached to the second surface 112 of the glass core layer 110. The third UD layer 131 may include a third fiber bundle f3 extending in the first direction D1.

The fourth UD layer 132 may be laminated on a rear surface of the third UD layer 131. The fourth UD layer 132 may be disposed to face the chassis 10 (see FIG. 2). The fourth UD layer 132 may include a fourth fiber bundle f4 extending in the second direction D2.

For example, referring to FIG. 12, the frame 100 may include the glass core layer 110, the first fiber-reinforced layer 120 configured as a 3-ply structure of a UD series, and a second fiber-reinforced layer 130 configured as a 3-ply structure of a UD series.

The first fiber-reinforced layer 120 may include a fifth UD layer 123, a sixth UD layer 124, and a seventh UD layer 125.

The fifth UD layer 123 may be attached to the first surface 111 of the glass core layer 110. The first UD layer 121 may include a fifth fiber bundle f5 extending in the first direction D1.

The sixth UD layer 124 may be spaced apart from the fifth UD layer 123 in a forward (+X direction). The sixth UD layer 124 may be disposed to face the plurality of display modules 30A-30w (see FIG. 2). The sixth UD layer 124 may be configured to be in contact with the rear surface 302 (see FIGS. 3 and 14) of the plurality of display modules 30A-30w. The sixth UD layer 124 may include a sixth fiber bundle f6 extending in the first direction D1.

The seventh UD layer 125 may be disposed between the fifth UD layer 123 and the sixth UD layer 124. The seventh UD layer 125 may be attached to a front surface of the fifth UD layer 123 and a rear surface of the sixth UD layer 124. The seventh UD layer 125 may include a seventh fiber bundle f7 extending in the second direction D2.

The second fiber-reinforced layer 130 may include an eighth UD layer 133, a ninth UD layer 134, and a tenth UD layer 135.

The eighth UD layer 133 may be attached to the second surface 112 of the glass core layer 110. The eighth UD layer 133 may include an eighth fiber bundle f8 extending in the first direction D1.

The ninth UD layer 134 may be spaced apart from the eighth UD layer 133 in the rearward (−X direction). The ninth UD layer 134 may be disposed to face the chassis 10 (see FIG. 2). The ninth UD layer 134 may include a ninth fiber bundle f9 extending in the first direction D1.

The tenth UD layer 135 may be disposed between the eighth UD layer 133 and the ninth UD layer 134. The tenth UD layer 135 may be attached to a rear surface of the eighth UD layer 133 and a front surface of the ninth UD layer 134. The tenth UD layer 135 may include a tenth fiber bundle f10 extending in the second direction D2.

Meanwhile, although FIGS. 11 and 12 show the first direction D1 and the second direction D2 approximately intersecting, the present disclosure is not limited thereto. In addition, although FIGS. 11 and 12 show the first direction D1 approximately corresponding to the vertical direction (Z direction) and the second direction D2 approximately corresponding to the horizontal direction (Y direction), the present disclosure is not limited thereto. It is sufficient that the first direction D1 and the second direction D2 are different from each other, and the first direction D1 and the second direction D2 may be defined in various directions, respectively.

FIG. 13 is a cross-sectional view of the plurality of display modules and the frame of the display apparatus according to an embodiment of the present disclosure. FIG. 14 is an enlarged cross-sectional view of a portion of the plurality of display modules and the frame of the display apparatus according to the embodiment of the present disclosure shown in FIG. 13.

FIG. 13 exemplarily shows three display modules 30A, 30H, and 30O of the plurality of display modules 30A-30w. The three display modules 30A, 30H, and 30O may be representative of the plurality of display modules 30A-30w. FIG. 14 is an enlarged view of a portion of the display module 30A and a portion of the display module 30H shown in FIG. 13. In FIGS. 13 and 14, the display modules may be shown schematically for ease of description. In FIGS. 13 and 14, only main configurations are shown for ease of description, and some configurations may be omitted.

Referring to FIGS. 13 and 14, the frame 100 may be configured to support the plurality of display modules 30A-30w. The plurality of display modules 30A-30w may be arranged on the frame 100. The rear surface 302 of the plurality of display modules 30A-30w may be attached to the frame 100. The rear surface 302 of the plurality of display modules 30A-30w may be attached to the first fiber-reinforced layer 120 of the frame 100. In an example, each of the plurality of display modules 30A-30w may be mounted on the first fiber-reinforced layer 120 of the frame 100 via an adhesive member. In an example, the adhesive member may be provided on the rear surface 302 of each display module. The rear surface 302 of the plurality of display modules 30A-30w and the first fiber-reinforced layer 120 of the frame 100 may be in contact.

The frame 100 may be configured to maintain the constant gap g between the plurality of display modules 30A-30w. As described above, the coefficient of thermal expansion of the first fiber-reinforced layer 120 and the coefficient of thermal expansion of the second fiber-reinforced layer 130 may be configured to correspond to the coefficient of thermal expansion of the glass core layer 110, and the coefficient of thermal expansion of the first fiber-reinforced layer 120 may be configured to correspond to the coefficient of thermal expansion of the plurality of display modules 30A-30w. Thus, the frame 100 may expand or contract corresponding to the plurality of display modules 30A-30w, and the gap g may be maintained constant. When the gap g is maintained constant, the seam formed by the gap g may not be emphasized. As a result, the sense of unity of the screen of the display panel 20 may be maintained, thereby reducing visual discomfort for the user. Consequently, the display apparatus 1 may provide a seamless viewing environment, and user satisfaction may be increased.

According to an embodiment of the present disclosure, the coefficient of thermal expansion of the first fiber-reinforced layer 120 may be determined by (i.e., based on or corresponding to) the pitch p (hereinafter referred to as an inorganic light-emitting element pitch) between two adjacent inorganic light-emitting elements among the plurality of inorganic light-emitting elements 50. According to an embodiment of the present disclosure, the coefficient of thermal expansion of the second fiber-reinforced layer 130 may be determined by the inorganic light-emitting element pitch p. The inorganic light-emitting element pitch p may refer to a distance between a center of a first inorganic light-emitting element 50 and a center of a second inorganic light-emitting element 50 adjacent to the first inorganic light-emitting element 50. For example, considering Weber's law, when the inorganic light-emitting element pitch p is small, the change in the gap g due to thermal expansion (or thermal contraction) may be relatively prominent. For example, considering Weber's law, when the inorganic light-emitting element pitch p is small, the change in the gap g due to thermal expansion (or thermal contraction) may not be relatively prominent. In other words, the larger the inorganic light-emitting element pitch p, the less sensitively the user may perceive the change in the gap g. Accordingly, the larger the inorganic light-emitting element pitch p, the more the first fiber-reinforced layer 120 may allow a material or weaving method with a large coefficient of thermal expansion. The larger the inorganic light-emitting element pitch p, the more the second fiber-reinforced layer 130 may allow a material or weaving method with a large coefficient of thermal expansion.

According to an embodiment of the present disclosure, as the inorganic light-emitting element pitch p increases, the weaving method of the first fiber-reinforced layer 120 may be configured to be applied in the order of UD, Satin, Twill, and Plain methods. As described above, this is because the coefficient of thermal expansion of the first fiber-reinforced layer 120 increases in the order of UD, Satin, Twill, and Plain methods. In an example, the coefficient of thermal expansion of the first fiber-reinforced layer 120 when manufactured by a UD weaving method may be smaller than the coefficient of thermal expansion of the first fiber-reinforced layer 120 when manufactured by a Plain weaving method.

According to an embodiment of the present disclosure, as the inorganic light-emitting element pitch p increases, the weaving method of the second fiber-reinforced layer 130 may be configured to be applied in the order of UD, Satin, Twill, and Plain methods. As described above, this is because the coefficient of thermal expansion of the second fiber-reinforced layer 130 increases in the order of UD, Satin, Twill, and Plain methods. In an example, the coefficient of thermal expansion of the second fiber-reinforced layer 130 when manufactured by a UD weaving method may be smaller than the coefficient of thermal expansion of the second fiber-reinforced layer 130 when manufactured by a Plain weaving method.

For example, when the inorganic light-emitting element pitch p is less than a first reference pitch (e.g., approximately 0.84 mm), the first fiber-reinforced layer 120 and the second fiber-reinforced layer 130 may be formed by a UD weaving method. For example, when the inorganic light-emitting element pitch p is greater than or equal to the first reference pitch and less than a second reference pitch (e.g., approximately 1.0 mm), the first fiber-reinforced layer 120 and the second fiber-reinforced layer 130 may be formed by a UD weaving method, a Satin weaving method, or a Twill weaving method. For example, when the inorganic light-emitting element pitch p is greater than or equal to the second reference pitch, the first fiber-reinforced layer 120 and the second fiber-reinforced layer 130 may be formed by a UD weaving method, a Satin weaving method, a Twill weaving method, or a Plain weaving method. Meanwhile, it should be appreciated that the first reference pitch and the second reference pitch may vary depending on the size, configurations, and the like of the display apparatus 1.

According to various embodiments of the present disclosure, a display apparatus may include the plurality of display modules 30A-30w, each including the substrate 40 and the plurality of inorganic light-emitting elements 50 mounted on the substrate; and the frame 100 configured to support the plurality of display modules such that the plurality of display modules are arranged horizontally in an M*N matrix form. The frame 100 may include the glass core layer 110. The frame 100 may include the first fiber-reinforced layer 120 attached to the first surface 111 of the glass core layer and configured to face the substrates of the plurality of display modules. The frame 100 may include the second fiber-reinforced layer 130 attached to the second surface 112 of the glass core layer opposite to the first surface.

The first fiber-reinforced layer 120 may include at least one of CFRP and GFRP.

The second fiber-reinforced layer 130 may include at least one of CFRP and GFRP.

The first fiber-reinforced layer 120 and the second fiber-reinforced layer 130 may be made of the same material.

A coefficient of thermal expansion of the first fiber-reinforced layer 120 may be configured to correspond to a coefficient of thermal expansion of the glass core layer 110. A coefficient of thermal expansion of the second fiber-reinforced layer 130 may be configured to correspond to the coefficient of thermal expansion of the glass core layer 110.

The coefficient of thermal expansion of the first fiber-reinforced layer 120 may be determined by the pitch p between two adjacent inorganic light-emitting elements among the plurality of inorganic light-emitting elements 50. The coefficient of thermal expansion of the second fiber-reinforced layer 130 may be determined by the pitch p between two adjacent inorganic light-emitting elements among the plurality of inorganic light-emitting elements 50.

The coefficient of thermal expansion of the first fiber-reinforced layer 120 may be determined by a weaving method of the first fiber-reinforced layer 120. The first fiber-reinforced layer 120 may be configured to be woven by a Plain, Twill, Satin, or UD method.

The coefficient of thermal expansion of the second fiber-reinforced layer 130 may be determined by a weaving method of the second fiber-reinforced layer 130. The second fiber-reinforced layer 130 may be configured to be woven by a Plain, Twill, Satin, or UD method.

As the pitch p between two adjacent inorganic light-emitting elements among the plurality of inorganic light-emitting elements 50 increases, the weaving method of the first fiber-reinforced layer 120 may be configured to be applied in the order of UD, Satin, Twill, and Plain methods.

As the pitch p between two adjacent inorganic light-emitting elements among the plurality of inorganic light-emitting elements 50 increases, the weaving method of the second fiber-reinforced layer 130 may be configured to be applied in the order of UD, Satin, Twill, and Plain methods.

When the first fiber-reinforced layer 120 and the second fiber-reinforced layer 130 are woven by a UD method, the first fiber-reinforced layer 120 may include the first UD layer 121 including the fiber bundle f1 extending in a first direction and attached to the first surface 111 of the glass core layer, and the second UD layer 122 including the fiber bundle f2 extending in a second direction different from the first direction and laminated on a front surface of the first UD layer 121, and configured to be in contact with the rear surface 302 of the plurality of display modules. When the first fiber-reinforced layer 120 and the second fiber-reinforced layer 130 are woven by a UD method, the second fiber-reinforced layer 130 may include the third UD layer 131 including the fiber bundle f3 extending in the first direction and attached to the second surface 112 of the glass core layer, and the fourth UD layer 132 including the fiber bundle f4 extending in the second direction and configured to be laminated on a rear surface of the third UD layer 131.

When the first fiber-reinforced layer 120 and the second fiber-reinforced layer 130 are woven by a UD method, the first fiber-reinforced layer 120 may include the first UD layer 123 including the fiber bundle f5 extending in a first direction and attached to the first surface 111 of the glass core layer, the second UD layer 124 including the fiber bundle f6 extending in the first direction and configured to be in contact with the rear surface 302 of the plurality of display modules, and the third UD layer 125 including the fiber bundle f7 extending in a second direction different from the first direction and disposed between the first UD layer 123 and the second UD layer 124. When the first fiber-reinforced layer 120 and the second fiber-reinforced layer 130 are woven by a UD method, the second fiber-reinforced layer 130 may include the fourth UD layer 133 including the fiber bundle f8 extending in the first direction and attached to the second surface 112 of the glass core layer, the fifth UD layer 134 including the fiber bundle f9 extending in the first direction and spaced apart rearwardly from the fourth UD layer 133, and the sixth UD layer 135 including the fiber bundle f10 extending in the second direction and disposed between the fourth UD layer 133 and the fifth UD layer 134.

Each of the plurality of inorganic light-emitting elements 50 may include the first semiconductor 58a; the second semiconductor 58b adjacent to the substrate more than the first semiconductor; the active layer 58c disposed between the first semiconductor and the second semiconductor and configured to generate light; the first contact electrode 57a electrically connected to the first semiconductor and disposed on an opposite side of the light-emitting surface 54 of the inorganic light-emitting element; and the second contact electrode 57b electrically connected to the second semiconductor and disposed on the opposite side of the light-emitting surface 54 of the inorganic light-emitting element. The substrate 40 may include the first pad electrode 44a configured to correspond to the first contact electrode; and the second pad electrode 44b configured to correspond to the second contact electrode. The display apparatus may further include the conductive adhesive layer 47 disposed at least partially between the first contact electrode 57a and the first pad electrode 44a and between the second contact electrode 57b and the second pad electrode 44b to electrically connect the plurality of inorganic light-emitting elements 50 and the substrate 40.

The display apparatus may further include the chassis 10 disposed to face the second fiber-reinforced layer 130 of the frame 100 and configured to cover a rear side of the plurality of display modules and a rear side of the frame.

The substrate 40 may include glass.

According to various exemplary embodiments of the present disclosure, a display apparatus may include the plurality of micro light-emitting diode (LED) modules 30A-30w; the frame 100 disposed to face rear surfaces of the plurality of micro LED modules and configured to maintain the gap g between the plurality of micro LED modules; and the chassis 10 configured to cover a rear side of the plurality of micro LED modules and a rear side of the frame. The frame 100 may include the first fiber-reinforced layer 120 disposed to face the rear surfaces of the plurality of micro LED modules and including at least one of carbon fiber reinforced polymer (CFRP) and glass fiber reinforced polymer (GFRP); the second fiber-reinforced layer 130 spaced rearwardly from the first fiber-reinforced layer, disposed to face the chassis, and made of the same material as the first fiber-reinforced layer; the glass core layer 110 disposed between the first fiber-reinforced layer 120 and the second fiber-reinforced layer 130; the first adhesive layer 140 disposed between the first fiber-reinforced layer 120 and the glass core layer 110 and configured to bond the first fiber-reinforced layer and the glass core layer; and the second adhesive layer 150 disposed between the second fiber-reinforced layer 130 and the glass core layer 110 and configured to bond the second fiber-reinforced layer and the glass core layer.

Each of the plurality of micro LED modules may include the glass substrate 40; and the plurality of micro LEDs 50 mounted on the glass substrate 40. Each of the plurality of micro LEDs may include the first semiconductor 58a; the second semiconductor 58b adjacent to the glass substrate more than the first semiconductor; and the active layer 58c disposed between the first semiconductor and the second semiconductor and configured to generate light.

A coefficient of thermal expansion of the first fiber-reinforced layer 120 and a coefficient of thermal expansion of the second fiber-reinforced layer 130 may be configured to correspond to a coefficient of thermal expansion of the glass core layer 110.

The coefficient of thermal expansion of the first fiber-reinforced layer 120 and the coefficient of thermal expansion of the second fiber-reinforced layer 130 may be determined by the pitch p between two adjacent inorganic light-emitting elements among the plurality of inorganic light-emitting elements 50.

The coefficient of thermal expansion of the first fiber-reinforced layer 120 may be determined by (i.e., based on, or corresponding to) a weaving method of the first fiber-reinforced layer, and the coefficient of thermal expansion of the second fiber-reinforced layer 130 may be determined by a weaving method of the second fiber-reinforced layer. Each of the first fiber-reinforced layer 120 and the second fiber-reinforced layer 130 may be configured to be woven by a Plain, Twill, Satin, or Unidirectional (UD) method.

The display apparatus 1 according to various embodiments of the present disclosure may include the frame 100 including the glass core layer 110, the first fiber-reinforced layer 120, and the second fiber-reinforced layer 130. Since the frame 100 does not include a steel material, it may be relatively light in weight and thin in thickness. In addition, a coefficient of thermal expansion of the frame 100 may be configured to be the same as/substantially similar to a coefficient of thermal expansion of a plurality of display modules, and as a result, the gap g between the plurality of display modules may be kept constant.

The effects to be obtained from the present disclosure are not limited to the effects mentioned above, and other unmentioned effects can be clearly understood by those of ordinary skill in the art to which the present disclosure pertains from the description below.

While the present disclosure has been particularly described with reference to exemplary embodiments, it should be understood by those of skilled in the art that various changes in form and details may be made without departing from the spirit and scope of the present disclosure.

What is claimed is:

1. A display apparatus comprising:
a plurality of display modules, one or more of the plurality of display modules comprising a substrate and a plurality of inorganic light-emitting elements mounted on the substrate; and
a frame configured to support the plurality of display modules such that the plurality of display modules are arranged horizontally in an M*N matrix form;
wherein the frame comprises:
a glass core layer,
a first fiber-reinforced layer on a first surface of the glass core layer and configured to face the substrates of the plurality of display modules, and
a second fiber-reinforced layer on a second surface of the glass core layer opposite to the first surface.

2. The display apparatus of claim 1, wherein
the first fiber-reinforced layer comprises at least one of carbon fiber reinforced polymer (CFRP) and glass fiber reinforced polymer (GFRP).

3. The display apparatus of claim 1, wherein
the second fiber-reinforced layer comprises at least one of carbon fiber reinforced polymer (CFRP) or glass fiber reinforced polymer (GFRP).

4. The display apparatus of claim 1, wherein
the first fiber-reinforced layer and the second fiber-reinforced layer comprise a same material.

5. The display apparatus of claim 1, wherein
a coefficient of thermal expansion of the first fiber-reinforced layer and a coefficient of thermal expansion of the second fiber-reinforced layer are configured to correspond to a coefficient of thermal expansion of the glass core layer.

6. The display apparatus of claim 1, wherein
a coefficient of thermal expansion of the first fiber-reinforced layer and a coefficient of thermal expansion of the second fiber-reinforced layer are determined by a pitch between two adjacent inorganic light-emitting elements among the plurality of inorganic light-emitting elements.

7. The display apparatus of claim 6, wherein
the coefficient of thermal expansion of the first fiber-reinforced layer is determined by a weave of the first fiber-reinforced layer, and
the first fiber-reinforced layer comprises at least one of the following weaves: Plain, Twill, Satin, or Unidirectional (UD).

8. The display apparatus of claim 6, wherein
the coefficient of thermal expansion of the second fiber-reinforced layer is determined by a weave of the second fiber-reinforced layer, and
the second fiber-reinforced layer comprises at least one of the following weaves:
Plain, Twill, Satin, or Unidirectional (UD).

9. The display apparatus of claim 7, wherein
as the pitch between two adjacent inorganic light-emitting elements among the plurality of inorganic light-emitting elements increases, the weave of the first fiber-reinforced layer is configured to be applied in the order of UD, Satin, Twill, and Plain.

10. The display apparatus of claim 8, wherein
as the pitch between two adjacent inorganic light-emitting elements among the plurality of inorganic light-emitting elements increases, the weave of the second fiber-reinforced layer is configured to be applied in the order of UD, Satin, Twill, and Plain.

11. The display apparatus of claim 1, wherein
based on the first fiber-reinforced layer and the second fiber-reinforced layer comprising a Unidirectional (UD) weave,
the first fiber-reinforced layer comprises:
a first UD layer comprising a first fiber bundle extending in a first direction and on the first surface of the glass core layer, and
a second UD layer comprising a second fiber bundle extending in a second direction different from the first direction, laminated on a front surface of the first UD layer, and in contact with a rear surface of the plurality of display modules, and
the second fiber-reinforced layer comprises:
a third UD layer comprising a third fiber bundle extending in the first direction and attached to the second surface of the glass core layer, and
a fourth UD layer comprising a fourth fiber bundle extending in the second direction and laminated on a rear surface of the third UD layer.

12. The display apparatus of claim 1, wherein
based on the first fiber-reinforced layer and the second fiber-reinforced layer comprising a Unidirectional (UD) weave,
the first fiber-reinforced layer comprises:
a first UD layer comprising a first fiber bundle extending in a first direction and on the first surface of the glass core layer,
a second UD layer comprising a second fiber bundle extending in the first direction and in contact with a rear surface of the plurality of display modules, and
a third UD layer comprising a third fiber bundle extending in a second direction different from the first direction and between the first UD layer and the second UD layer, and
the second fiber-reinforced layer comprises:
a fourth UD layer comprising a fourth fiber bundle extending in the first direction and on the second surface of the glass core layer,
a fifth UD layer comprising a fifth fiber bundle extending in the first direction and apart rearwardly from the fourth UD layer, and
a sixth UD layer comprising a sixth fiber bundle extending in the second direction and between the fourth UD layer and the fifth UD layer.

13. The display apparatus of claim 12, wherein
one or more of the plurality of inorganic light-emitting elements comprises:
a first semiconductor;
a second semiconductor closer to the substrate than the first semiconductor;
an active layer between the first semiconductor and the second semiconductor and configured to generate light;
a first contact electrode electrically connected to the first semiconductor and disposed on a side opposite to a light-emitting surface of the inorganic light-emitting element; and
a second contact electrode electrically connected to the second semiconductor and disposed on the side opposite to the light-emitting surface of the inorganic light-emitting element;
the substrate comprises:
a first pad electrode connected to the first contact electrode; and
a second pad electrode connected to the second contact electrode, and
the display apparatus further comprises:
a conductive adhesive layer at least partially between the first contact electrode and the first pad electrode, and between the second contact electrode and the second pad electrode and electrically connected to the plurality of inorganic light-emitting elements and the substrate.

14. The display apparatus of claim 1, further comprising:
a chassis facing the second fiber-reinforced layer of the frame, and on a rear side of the plurality of display modules and a rear side of the frame.

15. The display apparatus of claim 1, wherein
the substrate comprises glass.
